(19) United States
(12) Patent Application Publication
(10) Pub. No.: US 2025/0374805 A1
(43) Pub. Date: Dec. 4, 2025

(54) DISPLAY MODULE AND METHOD OF MANUFACTURING THE DISPLAY MODULE

(71) Applicant: Samsung Display Co., LTD., Yongin-si (KR)

(72) Inventors: SANGDUK LEE, Yongin-si (KR); HOIKWAN LEE, Yongin-si (KR)

(21) Appl. No.: 19/072,477

(22) Filed: Mar. 6, 2025

(30) Foreign Application Priority Data
May 30, 2024 (KR) 10-2024-0070466

(51) Int. Cl. H10K 59/80; H10K 59/12; H10K 59/131

(52) U.S. Cl. CPC H10K 59/873; H10K 59/1201; H10K 59/131; H10K 59/8791

(57) ABSTRACT

A manufacturing method of a display module includes providing a preliminary display module including a base substrate including a display area and a non-display area, a pixel disposed on the base substrate, a dam portion disposed in the non-display area, and an encapsulation layer on the base substrate and covering the pixel and the dam portion, forming a film layer on the encapsulation layer. The film layer includes a first film portion extending toward the display area with respect to the dam portion and a second film portion extending from the first film portion toward a side surface of the base substrate and surrounding at least a portion of the first film portion. The method includes forming a resin layer on the film layer, wherein the resin layer includes a first resin portion, and cutting the second film portion and the second resin portion.

This application claims priority to Korean Patent Application No. 10-2024-0070466, filed on May 30, 2024, and all the benefits accruing therefrom under 35 U.S.C. § 119, the content of which in its entirety is herein incorporated by reference.

### BACKGROUND

### 1. Field

The present disclosure relates to a display module and a method of manufacturing the display module. More particularly, the present disclosure relates to a display module with improved impact resistance and a method of manufacturing the display module.

### 2. Description of Related Art

Multimedia electronic devices, such as, for example, televisions, mobile phones, tablet computers, navigation devices, and game devices, include a display module displaying an image.

The display module has various stacked structures. However, when the display module is designed to have a simplified structure and a smaller thickness for being relatively light in weight, an impact resistance reliability of the display module decreases.

### SUMMARY

The present disclosure provides a display module with improved impact resistance.

The present disclosure provides a method of manufacturing the display module.

Embodiments of the inventive concept provide a method of manufacturing a display module. The method includes providing a preliminary display module including a base substrate including a display area and a non-display area adjacent to the display area, a pixel disposed on the base substrate, a dam portion disposed in the non-display area, and an encapsulation layer disposed on the base substrate and covering the pixel and the dam portion, forming a film layer on the encapsulation layer, wherein the film layer includes a first film portion extending in a direction toward the display area with respect to the dam portion and a second film portion extending from the first film portion toward a side surface of the base substrate and surrounding at least a portion of the first film portion, forming a resin layer on the film layer, wherein the resin layer includes a first resin portion overlapping the first film portion and a second resin portion overlapping the second film portion, and cutting the second film portion and the second resin portion.

The forming of the film layer includes forming a coating of an adhesive material on the encapsulation layer.

The forming of the film layer includes disposing a capping film on the coating of the adhesive material and laminating the capping film.

The film layer has an isotropic optical property and has an acrylic-based polymer material.

The forming of the resin layer is performed by one of a dispensing process, an inkjet process, and a slit coating process.

The encapsulation layer includes a first inorganic layer, an organic layer, and a second inorganic layer, which are sequentially stacked, and the dam portion is covered by the first inorganic layer and the second inorganic layer.

The preliminary display module includes a dam pattern.

The dam portion is disposed relatively closer to an interior of the base substrate compared to the dam pattern.

A side surface of the resin layer and an upper surface of the resin layer are perpendicular to each other.

The method further includes forming an optical layer. The cutting of the second film portion and the second resin portion is performed by a laser cutting process using a laser emitter, and the optical layer is formed on the resin layer after the cutting of the second film portion and the second resin portion.

The method further includes forming a cover panel on a rear surface of the preliminary display module, forming a driving chip on the preliminary display module in the non-display area, and forming a circuit board on a rear surface of the cover panel.

A side surface of the film layer and a side surface of the resin layer are disposed more inward within the display module compared to an outer portion of the base substrate.

Embodiments of the inventive concept provide a method of manufacturing a display module. The method includes providing a preliminary display module including: a base substrate including a display area and a non-display area adjacent to the display area, a pixel disposed on the base substrate, a dam portion disposed in the non-display area, and an encapsulation layer covering the pixel, disposing an auxiliary film on the base substrate such that the auxiliary film overlaps the non-display area, forming a resin layer on the encapsulation layer and the auxiliary film, wherein the resin layer includes a resin overlap portion extending in a direction toward the display area with respect to the dam portion and a resin protruding portion extending from the resin overlap portion toward a side surface of the base substrate and overlapping at least a portion of the auxiliary film, removing the auxiliary film, and cutting at least a portion of the resin overlap portion.

The auxiliary film is a release film.

An outer surface of the auxiliary film is coated with a silicon release agent.

The auxiliary film has a thickness equal to or greater than a maximum height from an upper surface of a circuit element layer of the display module to an upper surface of the encapsulation layer.

The cutting of at least the portion of the resin overlap portion includes a laser cutting process, and a side surface of the resin layer and an upper surface of the resin layer are perpendicular to each other.

Embodiments of the inventive concept provide a display module including a base substrate including a display area and a non-display area adjacent to the display area, a circuit element layer disposed on the base substrate, an encapsulation layer disposed on the circuit element layer, a film layer which is disposed on the encapsulation layer and optically transparent, a resin layer disposed on the film layer, and an optical layer disposed on the resin layer.

A side surface of the film layer and a side surface of the resin layer are aligned with each other in a direction.

The base substrate includes a glass material, and the film layer has an isotropic optical property.

The display module further includes an adhesive layer disposed between the encapsulation layer and the film layer.

A mounting area is defined in the non-display area.

The display module further includes a driving chip disposed on the circuit element layer in the mounting area.

The side surface of the resin layer and the side surface of the film layer are not in contact with the driving chip.

The display module further includes a cover panel disposed on a rear surface of the base substrate, a driving chip disposed on the base substrate in the non-display area, a printed circuit board disposed on a lower surface of the cover panel, and a flexible circuit film electrically connecting a lower surface of the printed circuit board and the circuit element layer of the display module.

According to the above, the method of manufacturing the display module improves the reliability in impact resistance of the display module.

According to the above, the method of manufacturing the display module includes the cutting of the resin layer after a protective film or the resin layer is formed on the encapsulation layer, and thus, the optical layer with a flat upper surface is provided in the display module.

According to the above, the impact resistance of the display module is enhanced.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a perspective view of a display device according to an embodiment of the present disclosure;

FIG. 2A is an exploded perspective view of a display device according to an embodiment of the present disclosure;

FIG. 2B is a block diagram of an electronic apparatus according to an embodiment of the inventive concept;

FIG. 3 is a cross-sectional view of a display module taken along a line I-I′ of FIG. 2A;

FIG. 4A is a cross-sectional view of a display module taken along a line II-II′ of FIG. 2A;

FIG. 4B is an enlarged view of an area AA′ of FIG. 4A;

FIG. 5 is a flowchart illustrating a method of manufacturing a display module according to an embodiment of the present disclosure;

FIGS. 6A and 6B are views illustrating a method of manufacturing a display module according to an embodiment of the present disclosure;

FIGS. 7A and 7B are views illustrating a method of forming a resin layer of a manufacturing method of a display module according to an embodiment of the present disclosure;

FIGS. 8A to 8D are views illustrating a method of manufacturing a display module according to an embodiment of the present disclosure;

FIG. 9A is a cross-sectional view of a display module according to an embodiment of the present disclosure;

FIG. 9B is a flowchart illustrating a method of manufacturing a display module according to an embodiment of the present disclosure; and

FIGS. 10A to 10E are views of a method of manufacturing a display module according to an embodiment of the present disclosure.

### DETAILED DESCRIPTION

The present disclosure may be variously modified and realized in many different forms, and thus specific example embodiments will be illustrated in the drawings and described in detail hereinbelow. However, the present disclosure should not be limited to the specific disclosed forms, and be construed to include all modifications, equivalents, or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, or the like may be used herein to describe various elements, these elements should not be limited by these terms. These terms are used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as illustrated in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

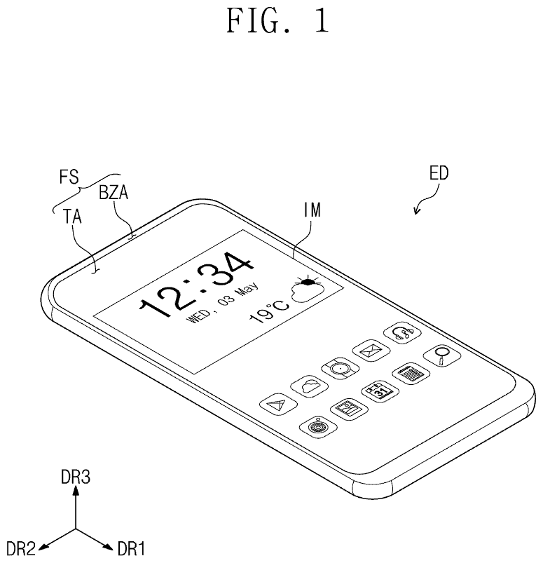

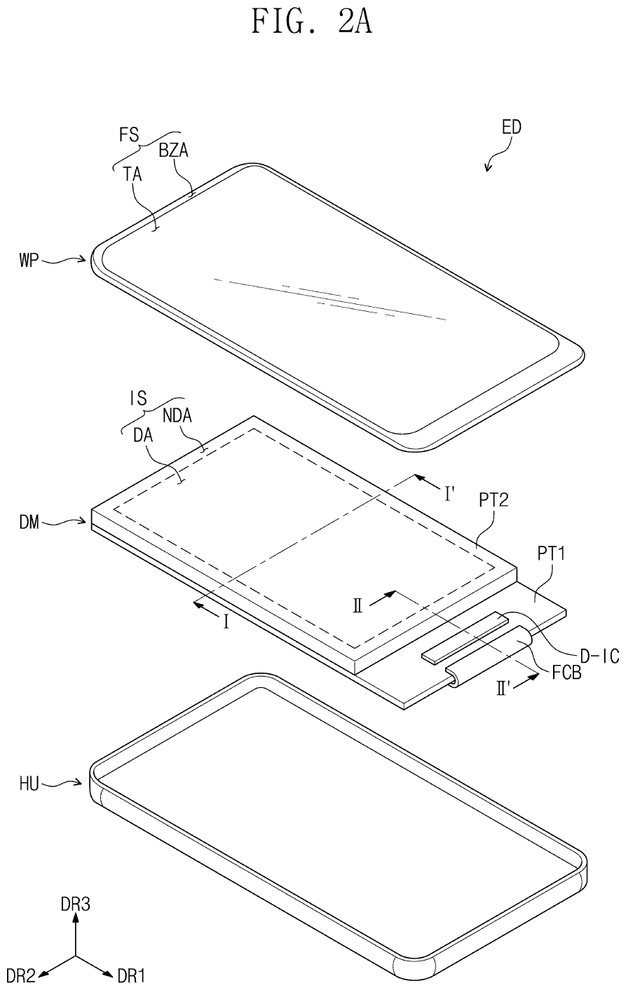

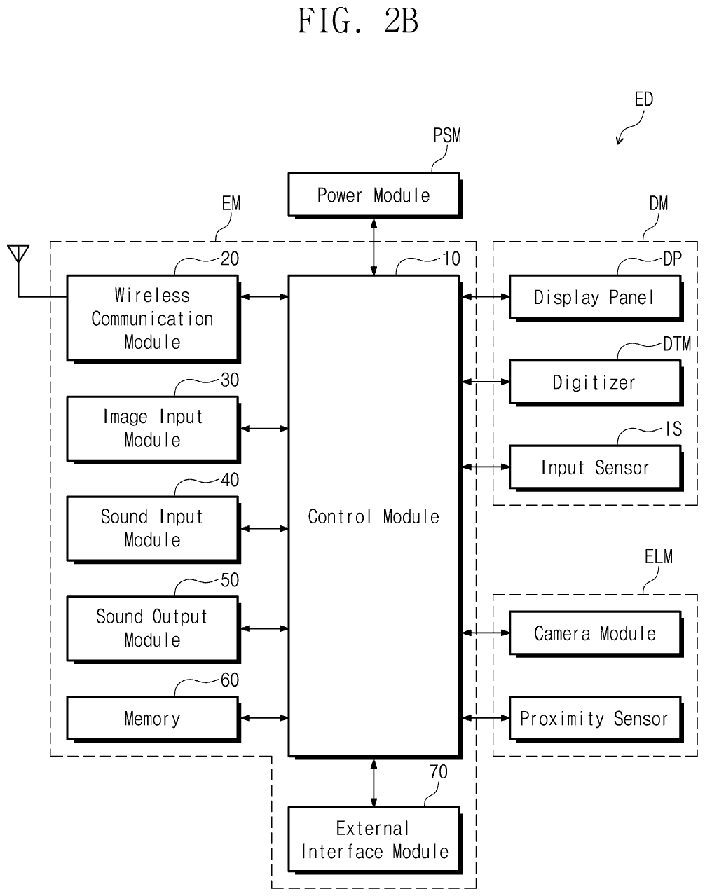

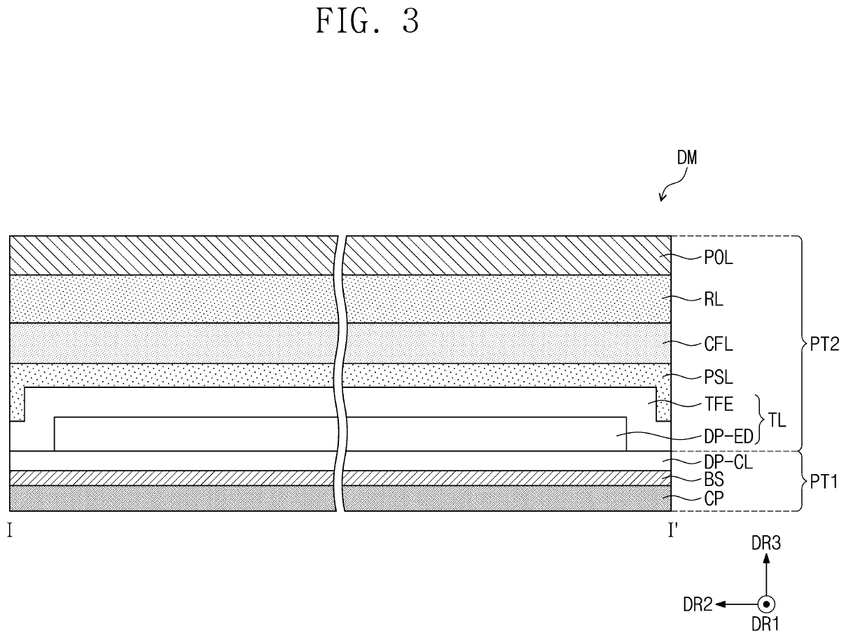

FIG. 1 is a perspective view of a display device ED according to an embodiment of the present disclosure. FIG. 2A is an exploded perspective view of the display device ED according to an embodiment of the present disclosure. FIG. 2B is a block diagram of an electronic apparatus according to an embodiment of the inventive concept; FIG. 3 is a cross-sectional view of a display module DM taken along a line I-I′ of FIG. 2A.

Referring to FIG. 1, the display device ED may be activated in response to electrical signals and may display an image. The display device ED may be applied to various embodiments to provide various users with the image. FIG. 1 illustrates a mobile phone as the display device ED, however, the present disclosure should not be limited thereto or thereby. As an example, the display device ED may be applied to a large-sized electronic item, such as, for example, a television set or an outdoor billboard or may be applied to a small and medium-sized electronic item, such as, for example, a monitor, a tablet computer, a navigation unit, a game unit, or the like. In the present specification, the display device ED may also be expressed as an “electronic device”.

The display device ED may display the image IM through a display surface FS, which is substantially parallel to a plane defined by a first direction DR1 and a second direction DR2, toward a third direction DR3. The third direction DR3 may be substantially parallel to a normal line direction of the display surface FS. The display surface FS in which the image IM is displayed may correspond to a front surface of the display device ED. The image IM may include a video and a still image. FIG. 1 illustrates application icons as a representative example of the image IM.

In the present embodiment, front (or upper) and rear (or lower) surfaces of each member or each unit of the display device ED may be defined with respect to a direction in which the image IM is displayed. The front and rear surfaces may be opposite to each other in the third direction DR3, and a normal line direction of each of the front and rear surfaces may be substantially parallel to the third direction DR3.

A separation distance between the front and rear surfaces of the member (or the unit) may correspond to a thickness in the third direction DR3 of the member (or the unit). In the following descriptions, the expression “when viewed in a plane” means a state of being viewed in the third direction DR3. In the following descriptions, the expression “when viewed in a cross-section” means a state of being viewed in the first direction DR1 or the second direction DR2. Directions indicated by the first, second, and third directions DR1, DR2, and DR3 may be relative to each other and may be changed to other directions.

The display surface FS in which the image IM is displayed may correspond to the front surface of the display device ED and a front surface of a window WP (refer to FIG. 2A). Accordingly, the display surface of the display device ED, the front surface of the display device ED, and the front surface of the window WP will be assigned with the same reference numeral, for example, “FS”.

Referring to FIG. 2A, the display device ED may include the window WP, the display module DM, and a housing HU.

The window WP may transmit the image IM and may protect the display module DM from impacts applied to the display device ED. The window WP may include an optically transparent insulating material. As an example, the window WP may include a glass substrate or a synthetic resin film. In an example in which the window WP is the synthetic resin film, the window WP may include a polyimide (PI) film or a polyethylene terephthalate (PET) film.

The window WP may include a transmissive area TA and a bezel area BZA. A user may view the image IM (refer to FIG. 1) provided through the transmissive area TA corresponding to the front surface FS of the window WP. In FIGS. 1 and 2, the transmissive area TA has a quadrangular shape with rounded vertices, however, this is an example. The transmissive area TA may have a variety of shapes and should not be particularly limited.

The transmissive area TA may be an optically transparent area. The bezel area BZA may be an area having a relatively lower transmittance than the transmissive area TA. The bezel area BZA may have a predetermined color. The bezel area BZA may be disposed adjacent to the transmissive area TA and may surround at least a portion of the transmissive area TA. The transmissive area TA may have a shape defined by the bezel area BZA, however, the present disclosure should not be limited thereto or thereby. According to an embodiment, the bezel area BZA may be disposed adjacent to a single side of the transmissive area TA or may be partially omitted.

The display module DM may be disposed under the window WP. The display module DM may have a configuration that substantially generates the image IM (refer to FIG. 1). The image IM (refer to FIG. 1) generated by the display module DM may be displayed through a display surface IS and may be perceived by the user through the transmissive area TA.

The display module DM may be a light emitting type display module, however, it should not be particularly limited. As an example, the display module DM may be an organic light emitting display module, an inorganic light emitting display module, or a quantum dot light emitting display module.

The display module DM may include a display area DA and a non-display area NDA. The display area DA may be activated in response to electrical signals. The non-display area NDA may be covered by the bezel area BZA. The non-display area NDA may be defined adjacent to the display area DA. The non-display area NDA may surround the display area DA.

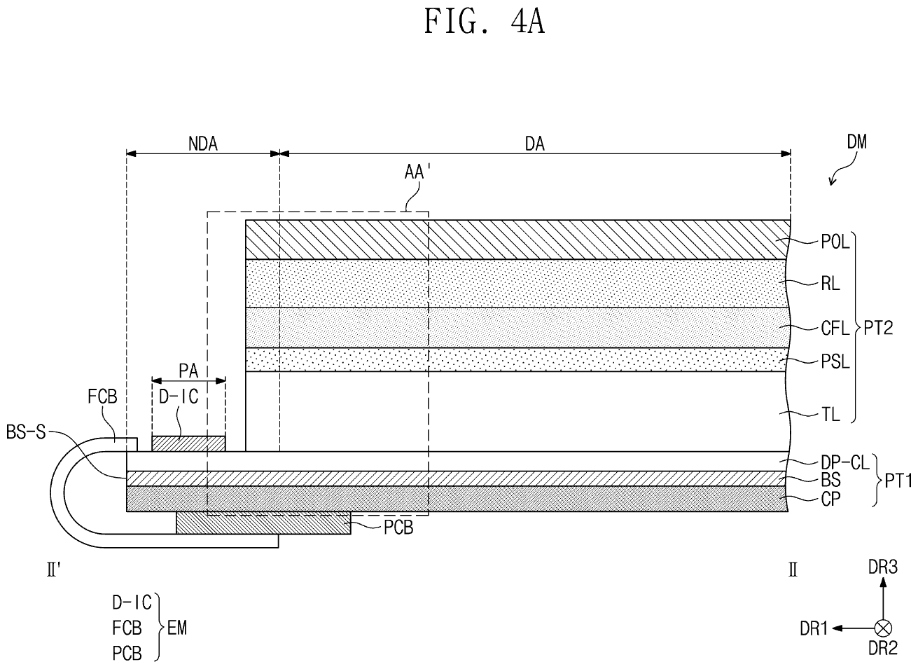

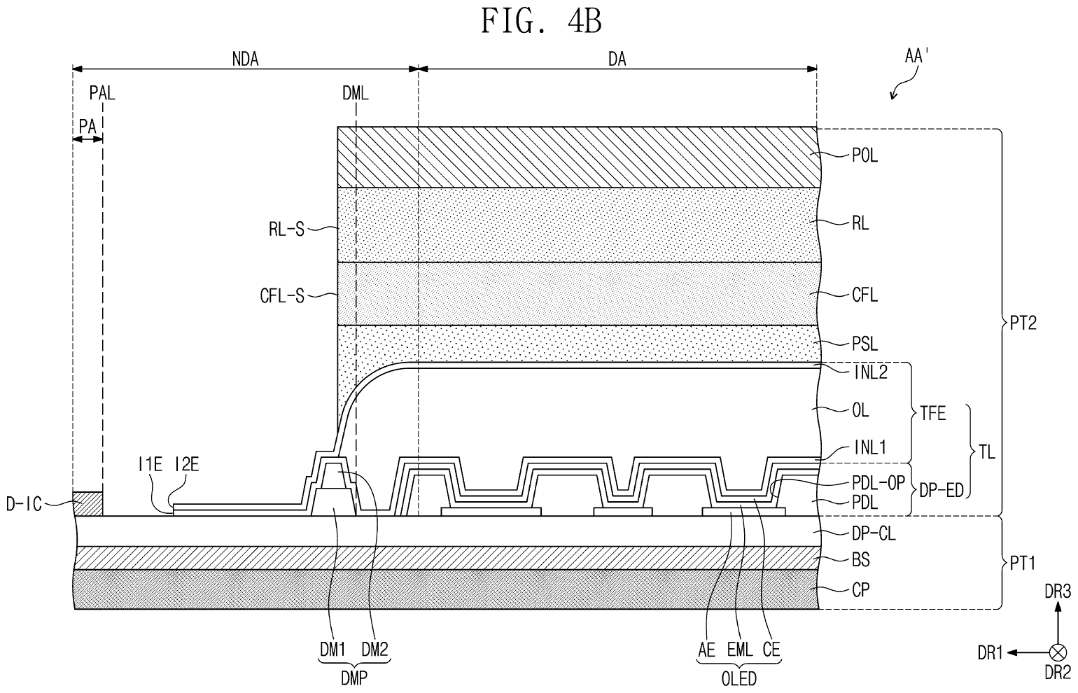

The display module DM may include a first module part PT1, a second module part PT2 disposed on the first module part PT1, a driving chip D-IC disposed on the first module part PT1, a flexible circuit film FCB, and a printed circuit board PCB (refer to FIG. 4A) disposed on a lower surface of the first module part PT1.

The housing HU may be disposed such that the housing HU covers the display module DM while exposing an upper surface of the display module DM, which is the display surface IS. The housing HU may cover a side surface and a bottom surface of the display module DM, and the upper surface of the display module DM may be entirely exposed, however, the present disclosure should not be limited thereto or thereby. According to an embodiment, the housing HU may further cover a portion of the upper surface of the display module DM as well as the side surface and the bottom surface of the display module DM. The housing HU may accommodate the display module DM and may protect the display module DM from external impacts.

As illustrated in FIG. 2B, the display device DD may further include an input sensor IS and a digitizer DTM. The input sensor IS detects a user's input. The input sensor IS that is a capacitance type may be disposed above the display panel DP. The digitizer DTM detects an input of a stylus pen. The digitizer DTM that is an electromagnetic induction-type may be disposed below the display panel DP.

The electronic module EM may include a control module 10, a wireless communication module 20, an image input module 30, a sound input module 40, a sound output module 50, a memory 60, an external interface module 70, and the like. The electronic module EM may include a main circuit board, and the foregoing modules may be mounted on the main circuit board, or electrically connected to the main circuit board through a flexible circuit board. The electronic module EM is electrically connected to the power module PSM.

Referring to FIG. 2B, the electronic module EM may be disposed in each of a first housing HM1 and a second housing HM2, and the power module PSM may be disposed in each of the first housing HM1 and the second housing HM2. Although not illustrated, the electronic module EM disposed in the first housing HM1 and the electronic module EM disposed in the second housing HM2 may be electrically connected to each other through the flexible circuit board.

The control module 10 controls the overall operation of the electronic apparatus ED. For example, the control module 10 activates or inactivates the display device DD to conform to a user's input. The control module 10 may control the image input module 30, the sound input module 40, the sound output module 50, and the like, to conform to the user's input. The control module 10 may include at least one microprocessor.

The wireless communication module 20 may transmit/receive a wireless signal to/from another terminal using a Bluetooth or WiFi channel. The wireless communication module 20 may transmit/receive an audio signal using a general communication channel. The wireless communication module 20 may include a plurality of antenna modules.

The image input module 30 processes an image signal and converts the image signal to image data displayable on the display device DD. The sound input module 40 receives an external sound signal through a microphone in a recording mode, an audio recognition mode, or the like, and converts the external audio signal to an electronic audio data. The sound output module 50 converts sound data received from the wireless communication module 20, or sound data stored in the memory 60, and outputs the converted sound data to the outside.

The external interface module 70 serves as an interface connected to an external charger, a wired/wireless data port, a card socket (e.g., a memory card and a SIM/UIM card), or the like.

The power module PSM supplies power supportive of the overall operation of the electronic apparatus ED. The power module PSM may include a general battery device.

The electro-optical module ELM may be an electronic component that outputs or receives an optical signal. The electro-optical module ELM may include a camera module and/or a proximity sensor. The camera module photographs an external image through the sensing area DP-TA.

Referring to FIG. 3, the display module may include the first module part PT1 and the second module part PT2 disposed on the first module part PT1.

The first module part PT1 may include a base substrate BS, a cover panel CP disposed on a rear surface of the base substrate BS, and a circuit element layer DP-CL disposed on the base substrate BS.

The second module part PT2 may include a display element layer DP-ED, an encapsulation layer TFE, an adhesive layer PSL, a film layer CFL, a resin layer RL, and an optical layer POL, which are sequentially stacked, however, the present disclosure should not be limited thereto or thereby. According to an embodiment, the film layer CFL may be omitted in the second module part PT2.

The base substrate BS may provide a base surface on which components included in the display module DM are stacked. The base substrate BS may be a glass substrate, however, the present disclosure should not be limited thereto or thereby. According to an embodiment, the base substrate BS may be an inorganic layer, an organic layer, or a composite material layer.

The cover panel CP may be disposed on the rear surface of the base substrate BS. In the present embodiment, the cover panel CP may be a directed coated cover panel (DCCP) formed on the rear surface of the base substrate BS. Although not illustrated separately, the cover panel CP may have a multi-layer structure including one or more layers among a reflective layer, a protective layer, a protective film layer, and a light blocking layer, however, the present disclosure should not be limited thereto or thereby. According to an embodiment, the cover panel CP may have a single-layer structure of composite materials.

The cover panel CP may perform one of the following functions, such as, for example, a heat dissipation function that dissipates heat generated from the display module DM, a light blocking function that blocks light directed toward a rear surface of the display module DM or emitted from the display module DM, a radio wave blocking function that blocks an electromagnetic interference (EMI) directed toward the display module DM, and a buffering function that protects the display module DM from external impacts.

The circuit element layer DP-CL may be disposed on the base substate BS. The circuit element layer DP-CL may include an insulating layer, a semiconductor pattern, a conductive pattern, and a signal line. An insulating layer, a semiconductor layer, and a conductive layer may be formed on the base substate BS by a coating or depositing process. Then, the insulating layer, the semiconductor layer, and the conductive layer may be selectively patterned through several photolithography processes. Accordingly, the semiconductor pattern, the conductive pattern, and the signal line included in the circuit element layer DP-CL may be formed.

An encapsulation element layer TL may be disposed on the circuit element layer DP-CL. In the present disclosure, the encapsulation element layer TL is defined for convenience of explanation and indicates a layer including the display element layer DP-ED and the encapsulation layer TFE.

The display element layer DP-ED may be disposed on the circuit element layer DP-CL. The display element layer DP-ED may include a light emitting element. As an example, the display element layer DP-ED may include an organic light emitting material, an inorganic light emitting material, an organic-inorganic light emitting material, a quantum dot, a quantum rod, a micro-LED, or a nano-LED.

The encapsulation layer TFE may be disposed on the display element layer DP-ED. The encapsulation layer TFE may protect the display element layer DP-ED from moisture, oxygen, or a foreign substance, e.g., dust particles. Accordingly, the encapsulation layer TFE may improve reliability of the display device ED. The encapsulation layer may have a structure in which an organic layer and an inorganic layer are alternately stacked with each other. This will be described in detail with reference to FIG. 4B.

The adhesive layer PSL may be disposed on the encapsulation layer TFE. The encapsulation layer TFE may be coupled with the film layer CFL by the adhesive layer PSL. The adhesive layer PSL may be a pressure sensitive adhesive (PSA), an optical clear adhesive (OCA), or an optical clear resin (OCR).

The film layer CFL may be disposed on the adhesive layer PSL. The film layer CFL may absorb a portion of external impacts applied to the encapsulation layer TFE and may transmit the light. The film layer CFL may be an isotropic transparent film. Accordingly, the image IM (refer to FIG. 1) generated by the display element layer DP-ED may be perceived by the user without being distorted. The film layer CFL may include an acrylic-based polymer material. However, the material for the film layer CFL should not be particularly limited as long as the material absorbs external impacts and has isotropic optical property.

The resin layer RL may be disposed on the film layer CFL. The resin layer RL may absorb a portion of external impacts applied to the film layer CFL and may transmit the light. The resin layer RL may have an isotropic optical property. The resin layer RL may include one of an epoxy-based polymer material, siloxane, and urethane.

The resin layer RL may have a relatively small modulus compared to the film layer CFL. Accordingly, the resin layer RL and the film layer CFL with different moduli may complementarily absorb external impacts. Thus, the display module DM may more effectively absorb external impacts when the display module DM includes both the resin layer RL and the film layer CFL than when the display module DM includes only one of the resin layer RL and the film layer CFL. That is, the reliability in impact resistance of the display module DM may be significantly improved. In some aspects, since materials included in the film layer CFL are cheaper than the resin used in a direct coating process, a manufacturing cost of the display module DM may be reduced.

The film layer CFL may provide a flat upper surface, and thus, the resin layer RL may be formed directly on the film layer CFL. Processes of forming the resin layer RL will be described later.

The optical layer POL may be disposed on the resin layer RL. The optical layer may include a polarizing film including a retarder and/or a polarizer, multiple layers of reflective layers that allow reflected light to destructively interfere with each other, or color filters disposed to correspond to an arrangement and emission color of pixels of a display unit.

The optical layer POL may be formed on the resin layer RL through a lamination process.

The display module DM may be an ultra-thin (UT) product. That is, the display module DM may correspond to a display module in which a separate member such as, for example, a cover glass is not placed on the optical layer POL such that the display module has a relatively small thickness.

However, in the case of a conventional display module, as the cover glass is omitted such that the display module has a relatively small thickness, the reliability in impact resistance is significantly reduced. In particular, the encapsulation layer is easily damaged due to external impacts, and foreign substances, such as, for example, moisture, oxygen, or the like, enter the encapsulation layer.

Different from the conventional display module, according to the manufacturing method of the display module DM of the present disclosure, the film layer CFL or the resin layer RL is disposed on the encapsulation layer TFE, and thus, the reliability in impact resistance may be improved.

However, when the resin layer RL is formed on the encapsulation layer TFE through the direct coating process, an end portion of the resin layer RL may not be flat. As an example, an edge bump protruded to the third direction DR3 or an edge slope recessed to the third direction DR3 may be formed in the end portion. In an example in which the end portion of the resin layer RL is not formed at a right angle, the process of laminating the optical layer POL may not be smoothly performed, and thus, the optical layer POL and the resin layer RL may be spaced apart from each other.

Different from the above, according to the manufacturing method of the display module of the present disclosure, the end portion of the resin layer RL may be formed at a right angle. Therefore, the process of laminating the optical layer POL may be smoothly performed. In some aspects, the reliability in impact resistance of the display module DM manufactured by the manufacturing method according to the present disclosure may be significantly improved.

Hereinafter, the manufacturing method of the display module and the display module manufactured by the manufacturing method will be described in detail.

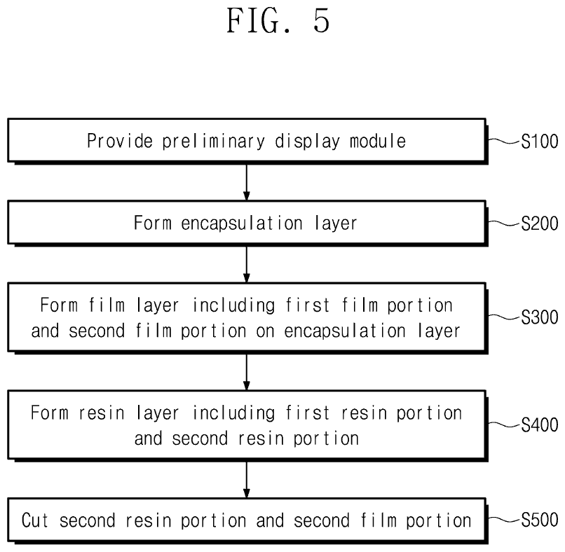

FIG. 4A is a cross-sectional view of the display module taken along a line II-II′ of FIG. 2A, and FIG. 4B is an enlarged view of an area AA′ of FIG. 4A. For the convenience of explanation, in the drawings of FIG. 4A and other drawings after FIG. 5, the laminated structure of the display element layer DP-ED and the encapsulation layer TFE will be omitted.

Referring to FIG. 4A, the display module DM may include a driving module EM.

The driving module EM may control a driving of the display module DM. The driving module EM may include the driving chip D-IC, the flexible circuit film FCB, and the printed circuit board PCB.

The driving chip D-IC may be disposed on the first module part PT1 such that the driving chip D-IC overlaps the non-display area NDA. The driving chip D-IC may be mounted on the first module part PT1 in the non-display area NDA. The driving chip D-IC may be disposed adjacent to a side portion of the second module part PT2. The driving chip D-IC may include driving circuits, e.g., a data driving circuit, to drive the pixels of the display module DM.

In the present disclosure, an area in which the driving chip D-IC is disposed on the upper surface of the first module part PT1 may be defined as a mounting area PA.

One end of the flexible circuit film FCB may be disposed at an edge of the upper surface of the first module part PT1, and the other end of the flexible circuit film FCB may be disposed under the first module part PT1. The other end of the flexible circuit film FCB may be in contact with the printed circuit board PCB. Accordingly, the flexible circuit film FCB may electrically connect the printed circuit board PCB and the circuit element layer DP-CL of the display module DM.

The flexible circuit film FCB may be a flexible film. Accordingly, the flexible circuit film FCB may be bent, and thus, the printed circuit board PCB may be disposed on a rear surface of the first module part PT1.

The flexible circuit film FCB may be attached to the non-display area NDA of the first module part PT1 through a bonding process. Although not illustrated in figures, the flexible circuit film FCB may be electrically connected to the display module DM through an anisotropic conductive adhesive layer.

The printed circuit board PCB may be disposed on a rear surface of the cover panel CP. Although not illustrated separately, controllers may be mounted on the printed circuit board PCB to control a driving of the pixels (not illustrated). In some aspects, a plurality of controllers may be further mounted on the printed circuit board PCB to control drivers.

Referring to FIG. 4B, the display element layer DP-ED may include a pixel definition layer PDL and a light emitting element OLED. The pixel definition layer PDL may be provided with a pixel opening PDL-OP defined therethrough.

Although not illustrated separately, the pixel may include the light emitting element OLED and a pixel driving circuit.

The light emitting element OLED may include a first electrode AE, a second electrode CE disposed on the first electrode AE, and a light emitting layer EML disposed between the first electrode AE and the second electrode CE. The first electrode AE may be disposed in the pixel opening PDL-OP and may be partially covered by the pixel definition layer PDL. Although not illustrated in separately, the first electrode AE may be connected to a transistor through a contact hole defined through the circuit element layer DP-CL.

In the present embodiment, the first electrode AE may correspond to an anode, and the second electrode CE may correspond to a cathode.

Referring to FIG. 4B, the encapsulation layer TFE may be disposed on the display element layer DP-ED and may cover the display element layer DP-ED. The encapsulation layer TFE may prevent moisture/oxygen or a foreign substance from entering the display element layer DP-ED to improve the reliability of the display element layer DP-ED.

The encapsulation layer TFE may include organic/inorganic layers. In the present embodiment, the encapsulation layer TFE may include a first inorganic layer INL1, an organic layer OL, and a second inorganic layer INL2.

The display module DM may include a dam portion DMP disposed on the first module part PT1. The dam portion DMP may be disposed on the first module part PT1 in the non-display area NDA. The dam portion DMP may surround the display area DA when viewed in the plane. The dam portion DMP may prevent an organic material used to form the organic layer OL from overflowing toward an edge direction of the base substrate BS in a process of forming the encapsulation layer TFE.

The dam portion DMP may be formed through the same process as a portion of the insulating layer included in the circuit element layer DP-CL or the pixel definition layer PDL.

FIG. 4B illustrates one dam portion DMP including a first layer DM1 and a second layer DM2 disposed on the first layer DM1 as a representative example, however, the stacked structure of a dam included in the display module DM and the number of the dams should not be limited thereto or thereby.

As an example, the display module DM may include a plurality of the dams to prevent the organic material from overflowing. In this case, a dam closest to the display area DA may be referred to as the “dam portion DMP”, and other dams may be referred to as a dam pattern (not illustrated). That is, the dam portion DMP may be disposed relatively closer to an interior of the base substrate BS compared to the dam pattern (not illustrated).

The stacked structure of the dam portion DMP should not be limited as illustrated in FIG. 4B. As an example, the dam portion DMP may have a multi-layer structure of three or more layers or a single-layer structure.

The dam portion DMP may be covered by the first inorganic layer INL1 and the second inorganic layer INL2.

For the convenience of explanation, a first boundary DML and a second boundary PAL are defined. An imaginary line extending from a portion of the dam portion DMP, which is closest to the display area DA, to the third direction DR3 may be referred to as the first boundary DML. An imaginary line extending from a portion of the mounting area PA, which is closest to the display area DA, to the third direction DR3 may be defined as the second boundary PAL. The second boundary PAL may be expressed as an imaginary line extending from a portion of the driving chip D-IC, which is closest to the display area DA, to the third direction DR3.

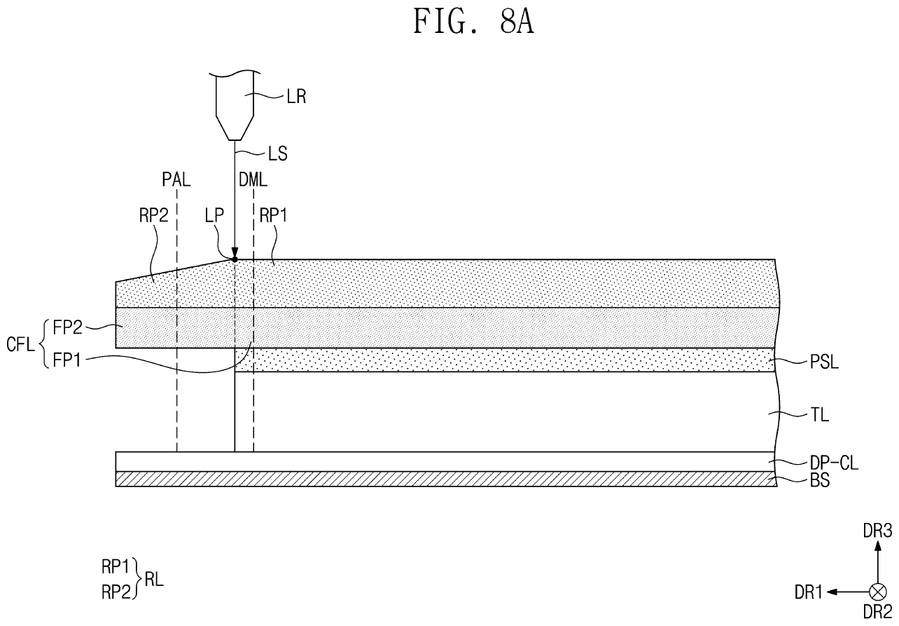

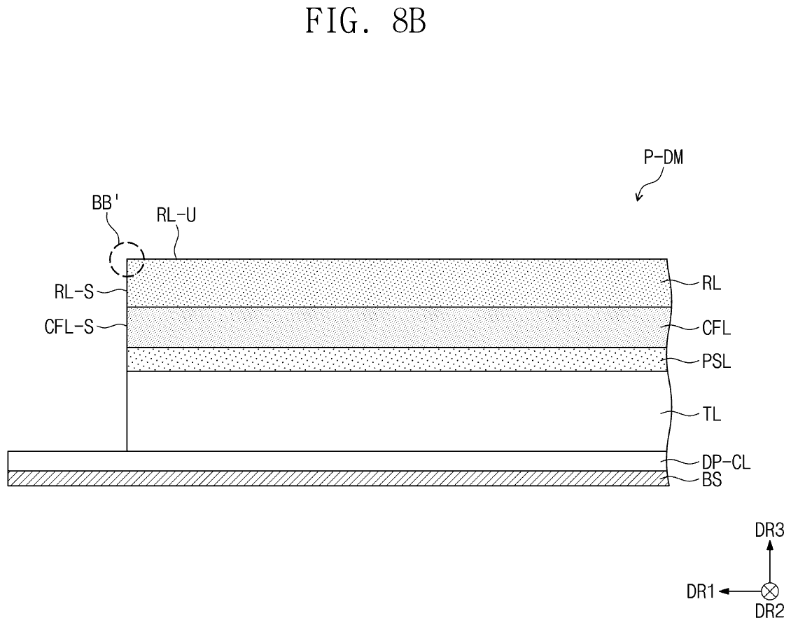

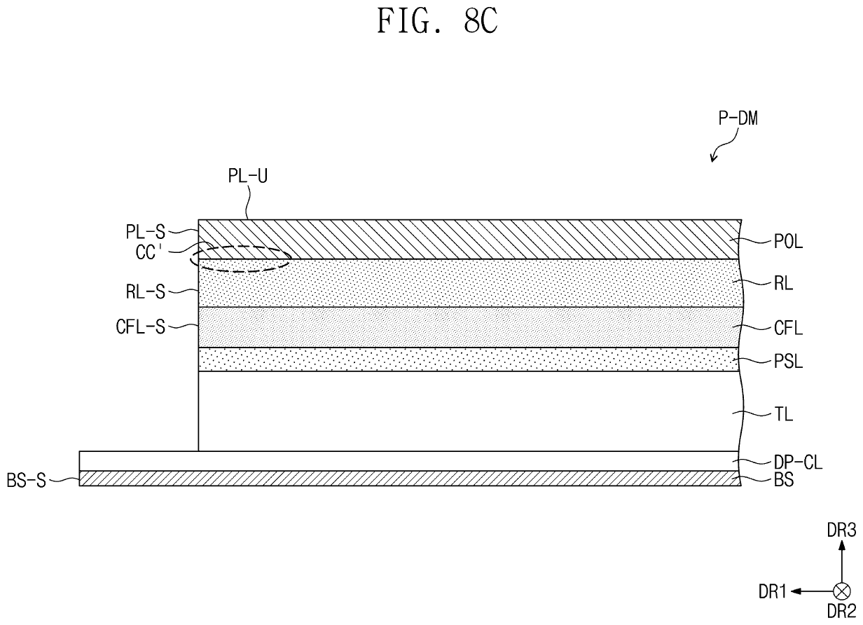

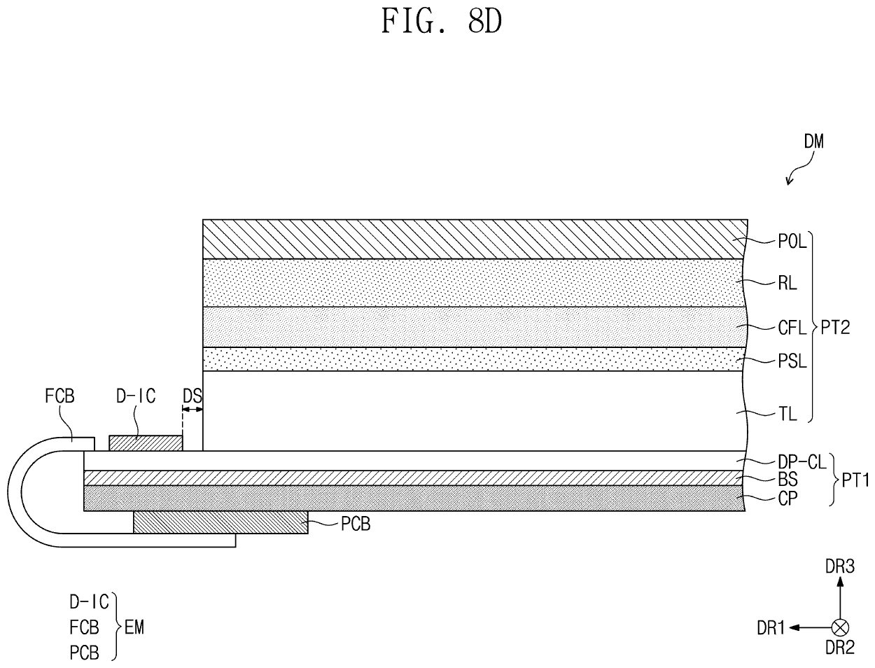

The first boundary DML and the second boundary PAL may serve as a reference to set a position of a cutting point LP (refer to FIG. 8A), and this will be described in detail with respect to FIG. 8A.

A side surface CFL-S of the film layer CFL and a side surface RL-S of the resin layer RL may be disposed between the first boundary DML and the second boundary PAL. Accordingly, a portion of the film layer CFL and a portion of the resin layer RL may overlap the dam portion DMP. In some aspects, the film layer CFL and the resin layer RL may be spaced apart from the driving chip D-IC. The side surface RL-S of the resin layer RL and the side surface CFL-S of the film layer CFL may not be in contact with the driving chip D-IC.

Edges of the film layer CFL and the resin layer RL may be supported by the dam portion DMP. Therefore, the structural stability of the film layer CFL and the resin layer RL may be improved. In some aspects, since the film layer CFL and the resin layer RL are spaced apart from the driving chip D-IC, the film layer CFL and the resin layer RL may not interfere with the process of mounting the driving chip D-IC.

An edge ILE of the first inorganic layer INL1 and an edge I2E of the second inorganic layer INL2 may be disposed between the first boundary DML and the second boundary PAL.

As illustrated in FIG. 4B, the upper surface of the resin layer RL-S may be flat. Accordingly, the optical layer POL may be adhered to the resin layer RL-S without being lifted.

In some aspects, as the resin layer RL and the film layer CFL are disposed on the encapsulation layer TFE, external impacts may be prevented from being transmitted to the encapsulation layer TFE. Accordingly, the reliability of the display module DM may be improved.

FIG. 5 is a flowchart illustrating a method of manufacturing the display module according to an embodiment of the present disclosure.

In the descriptions of the methods and processes herein, the operations may be performed in a different order than the order shown and/or described, or the operations may be performed in different orders or at different times. Certain operations may also be left out, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

The manufacturing method of the display module according to the present disclosure includes providing a preliminary display module including the base substrate including the display area and the non-display area adjacent to the display area, the pixel disposed on the base substrate, and the dam portion disposed in the non-display area (S100), forming the encapsulation layer on the base substrate such that the encapsulation layer covers the pixel (S200), forming the film layer on the encapsulation layer (S300), wherein the film layer includes a first film portion extending in a direction toward the display area with respect to the dam portion and a second film portion extending from the first film portion to ward a side surface of the base substrate and surrounding at least a portion of the first film portion, forming the resin layer, which includes a first resin portion overlapping the first film portion and a second resin portion overlapping the second film portion, on the film layer (S400), and cutting the second film portion and the second resin portion (S500). Cutting the second film portion and the second resin portion may include removing all or a portion of each of the second film portion and the second resin portion.

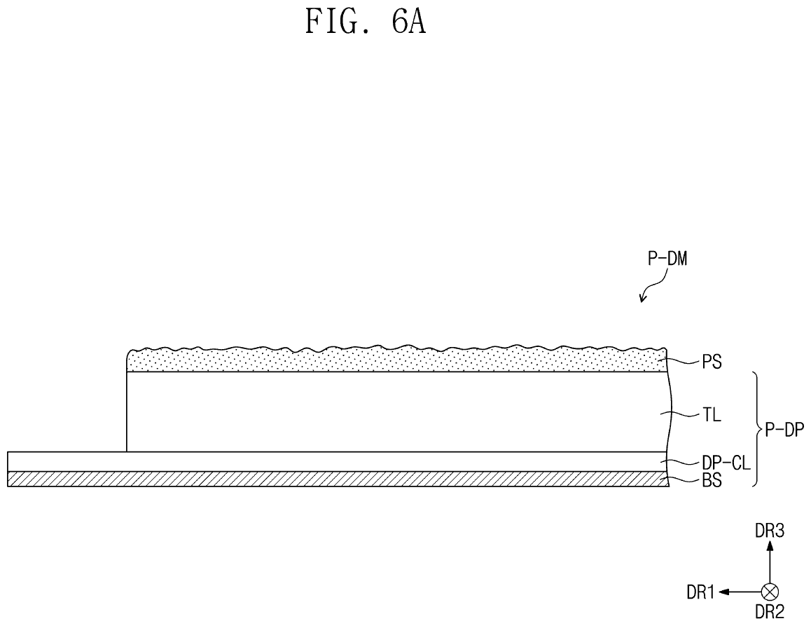

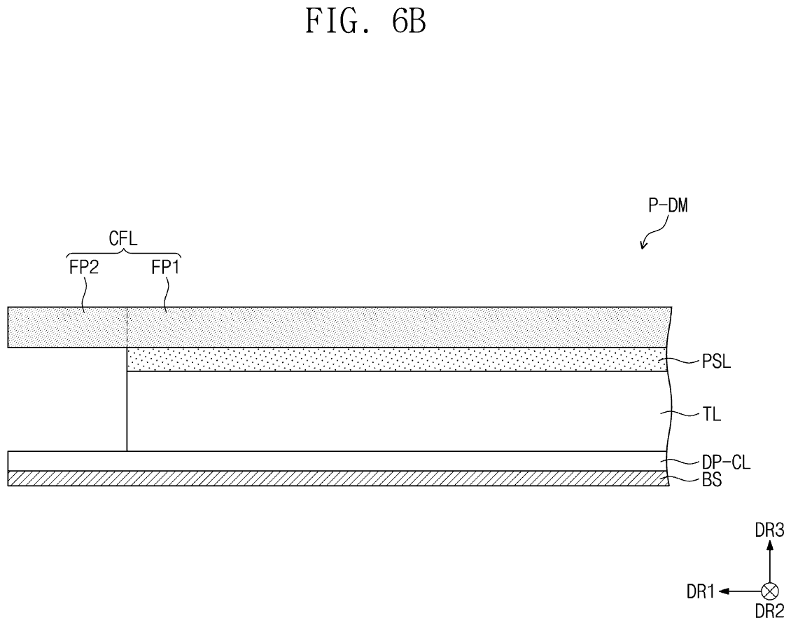

FIGS. 6A and 6B are views illustrating a method of manufacturing the display module according to an embodiment of the present disclosure.

In the present disclosure, the preliminary display module P-DM may be defined as a general term for a state before the display module DM is completed in the manufacturing process of the display module.

Referring to FIG. 6A, the method may include forming, on the preliminary display module P-DM, a coating of an adhesive material PS after providing the preliminary display module P-DM (S100, refer to FIG. 5) and forming the encapsulation layer TFE (refer to FIG. 4B) on the base substrate BS such that the encapsulation layer TFE covers the pixel (S200, refer to FIG. 5).

In FIG. 6A, the coating of the adhesive material PS including an optical transparent resin is a representative example, however, the coating process should not be limited to the coating of the adhesive material PS. According to an embodiment, a coating of a pressure sensitive adhesive (PSA) or an optical clear adhesive (OCA) may be applied or an adhesive film may be attached.

Then, referring to FIG. 6B, the method may include forming the film layer on the coating of the adhesive material PS (S300, refer to FIG. 5).

The forming of the film layer on the encapsulation layer (S300, refer to FIG. 5) may include performing a lamination process which applies a capping film over the coating of the adhesive material (i.e., laminates the coating of the adhesive material with the capping film). The adhesive material PS (refer to FIG. 6A) may be cured while the lamination process is performed, and thus, the adhesive layer PSL may be formed.

The film layer CFL may include the first film portion FP1 extending in a direction toward the display area DA with respect to the dam portion DMP (refer to FIG. 4B) and the second film portion FP2 protruded from the first film portion FP1 in a direction toward the side surface of the base substrate BS. The second film portion FP2 may cover at least a portion of the first film portion FP1.

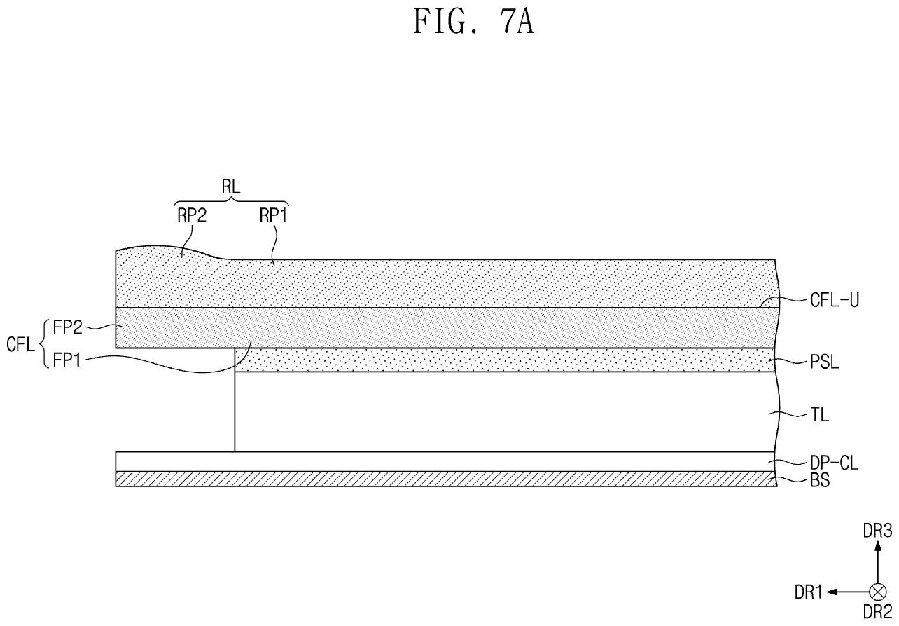

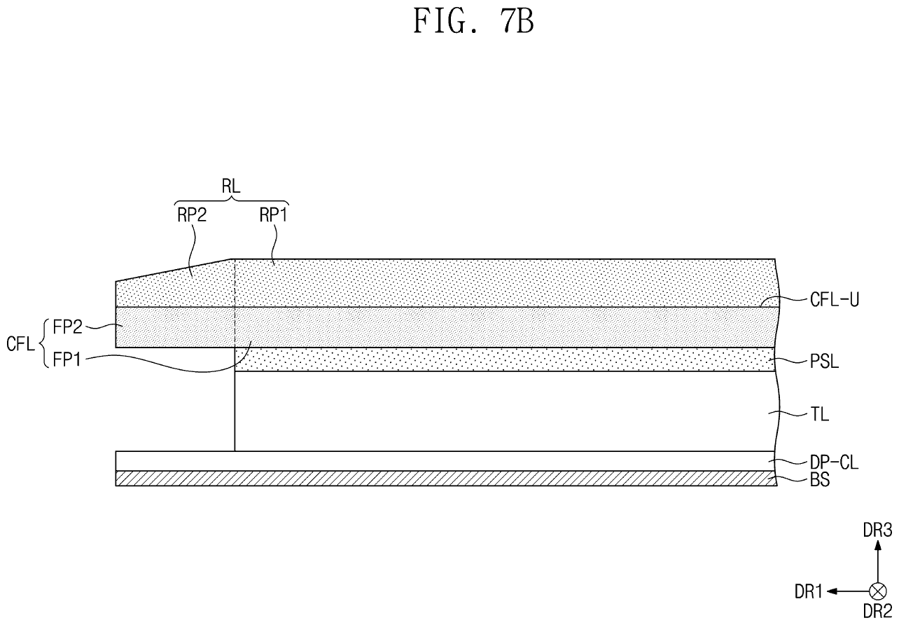

FIGS. 7A and 7B are views illustrating a method of forming the resin layer of a manufacturing method of the display module according to an embodiment of the present disclosure.

Referring to FIGS. 7A and 7B, the method may include forming the resin layer RL on the film layer CFL (S400, refer to FIG. 5).

The forming of the resin layer RL may include one of a dispensing process, an inkjet process, and a slit coating process. The resin layer RL may be directly coated onto the film layer CFL. The resin layer RL may include the first resin portion RP1 overlapping the first film portion FP1 and the second resin portion RP2 overlapping the second film portion FP2.

Since the film layer CFL provides a flat upper surface CFL-U, the resin layer RL may be formed with a flat shape on the film layer CFL. However, due to the characteristics of the direct coating process, an edge of the resin layer RL may be formed in an uneven shape.

FIG. 7A illustrates a structure in which the edge of the resin layer RL protrudes in the third direction DR3 and has an edge bump shape, and FIG. 7B illustrates a structure in which the edge of the resin layer RL is inclined toward the base substrate BS and has an edge slope shape.

In the present embodiment, the portion of the resin layer RL, which has the edge bump shape, and the portion of the resin layer RL, which has the edge slope shape, may be referred to as a portion with a non-flat shape.

The portion of the resin layer RL, which has the non-flat shape, may correspond to a portion of the second resin portion RP2. That is, according to the manufacturing method of the display module, the portion in which the non-flat shape is defined may be placed at a portion to be cut out (i.e., removed), which will be described later, and thus, the resin layer RL may be flattened.

Referring to FIG. 8A, the method may include cutting the second resin portion RP2 and the second film portion FP2 (S500, refer to FIG. 5).

The cutting process (S500, refer to FIG. 5) may include a laser cutting process. FIG. 8A illustrates a process of irradiating the cutting point LP with a laser light LS using a laser emitter LR.

The cutting point LP may be disposed between the first boundary DML and the second boundary PAL.

The method may include emitting or directing the laser light LS in a direction parallel to the third direction DR3 that is the normal line direction of the film layer CFL and the resin layer RL. For example, the laser light LS may be incident the film layer CFL and the resin layer RL in the direction parallel to the third direction DR3.

Then, FIG. 8B illustrates the preliminary display module P-DM from which the second film portion FP2 (refer to FIG. 8A) and the second resin portion RP2 (refer to FIG. 8A) are removed by the laser light LS (refer to FIG. 8A).

Since the second resin portion RP2 (refer to FIG. 8A) and the second film portion FP2 (refer to FIG. 8A) are removed by the same process, the side surface RL-S of the second resin portion and the side surface CFL-S of the second film portion may be substantially parallel to each other.

Since the laser light LS is emitted or directed in the direction parallel to the normal line direction of the resin layer RL and the film layer CFL (and incident the resin layer RL and the film layer CFL in the direction parallel to the normal line direction), the side surface RL-S of the resin layer RL and an upper surface RL-U of the resin layer RL may be perpendicular to each other. In an area BB′ of FIG. 8B, the side surface RL-S of the resin layer RL and the upper surface RL-U of the resin layer RL are illustrated as being perpendicular to each other. That is, the non-flat shape of the edge of the resin layer RL may be removed according to the manufacturing method of the display module of the present disclosure.

Then, referring to FIG. 8C, the method may include forming the optical layer on the resin layer RL. The resin layer RL may provide the flat upper surface RL-U (refer to FIG. 8B), and thus, the optical layer POL formed on the resin layer RL may be adhered to the resin layer RL without being lifted. In an area CC′ of FIG. 8C, the resin layer RL and the optical layer POL are illustrated as being adhered to each other.

The side surface CFL-S of the film layer and the side surface RL-S of the resin layer may be positioned more inward within the display module DM (refer to FIGS. 4A and FIG. 4B) compared to the side surface BS-S of the base substrate BS.

Referring to FIG. 8D, the method may include forming the cover panel CP on the rear surface of the preliminary display module P-DM (refer to FIG. 8C), and further, forming the driving module EM in the first module part PT1.

The forming of the driving module EM in the first module part PT1 may include forming the driving chip D-IC on an upper surface PU of the first module part PT1, forming the printed circuit board PCB on a lower surface of the cover panel CP, placing one end of the flexible circuit film FCB on the upper surface of the first module part PT1, and placing the other end of the flexible circuit film FCB on the lower surface of the printed circuit board. Although not illustrated separately, the method may include attaching the printed circuit board PCB to the lower surface of the cover panel CP using an adhesive layer.

The driving chip D-IC may be spaced apart from the second module part PT2 by a separation distance DS. Accordingly, during the mounting process of the driving chip D-IC, the second module part PT2 may not cause interference.

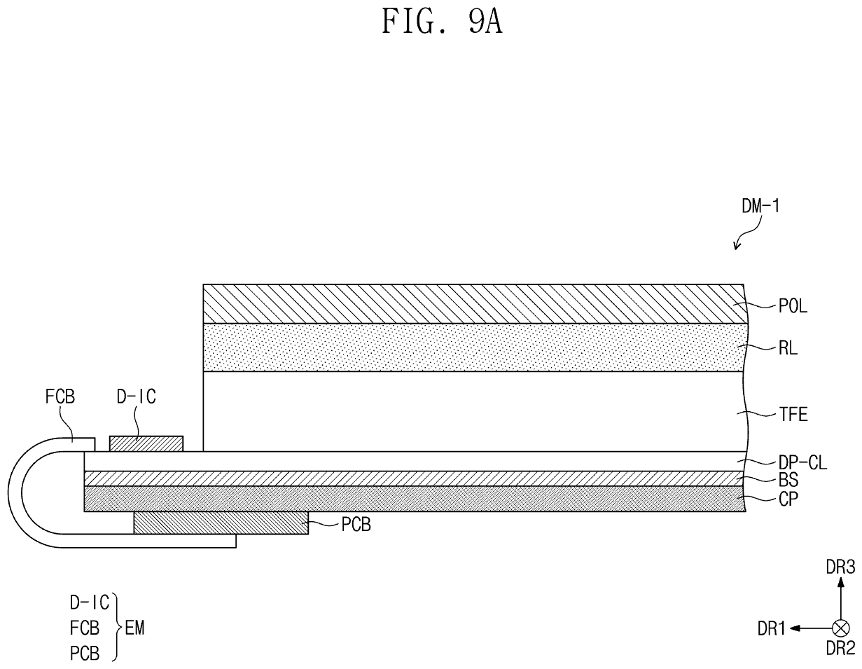

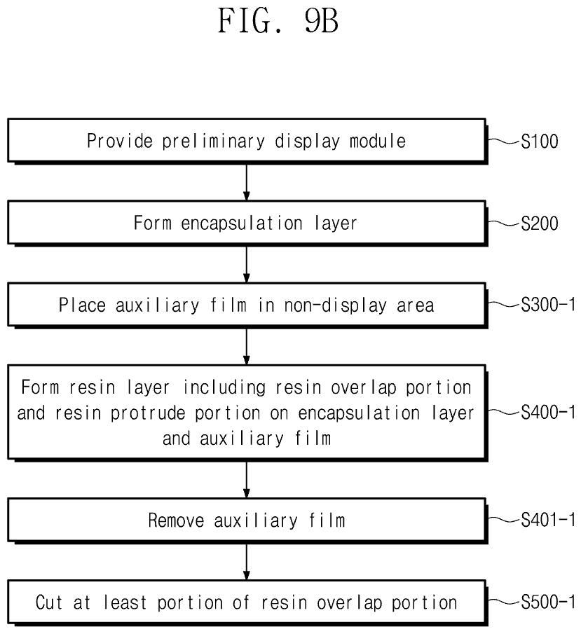

FIG. 9A is a cross-sectional view of a display module DM-1 according to an embodiment of the present disclosure. In FIG. 9A, the same reference numerals denote the same elements in FIGS. 4A and 4B, and thus, detailed descriptions of the same elements will be omitted.

Referring to FIG. 9A, the display module DM-1 has a structure from which a film layer (refer to CFL of FIG. 4A) is omitted when compared to the display module DM described with reference to FIG. 4A.

Accordingly, a resin layer RL may be disposed directly on an encapsulation layer TFE. Since the resin layer RL is formed through a direct coating process, a separate adhesive layer may not be disposed between the encapsulation layer TFE and the resin layer RL.

Accordingly, the display module DM-1 may have simplified stack structure compared to the display module DM described with reference to FIG. 4A. In some aspects, the display module DM-1 may have a relatively small thickness and be relatively lightweight compared to the display module DM described with reference to FIG. 4A.

FIG. 9B is a flowchart illustrating a method of manufacturing the display module DM-1 according to an embodiment of the present disclosure.

The manufacturing method of the display module illustrated in FIG. 9B is to manufacture the display module DM-1 illustrated in FIG. 9A.

Referring to FIG. 9B, the manufacturing method of the display module DM-1 may include providing a preliminary display module including a base substrate including a display area and a non-display area adjacent to the display area, a pixel disposed on the base substrate, and a dam portion disposed on the non-display area (S100), forming the encapsulation layer on the preliminary display module such that the encapsulation layer covers the pixel (S200), disposing an auxiliary film on the base substrate in the non-display area (S300-1), forming the resin layer on the encapsulation layer and the auxiliary film (S400-1), wherein the resin layer includes a resin overlap portion extending in a direction toward the display area with respect to the dam portion and a resin protruding portion protruding from the resin overlap portion toward a side surface of the base substrate and overlapping at least a portion of the auxiliary film, removing the auxiliary film (S401-1), and cutting at least a portion of the resin overlap portion (S500-1).

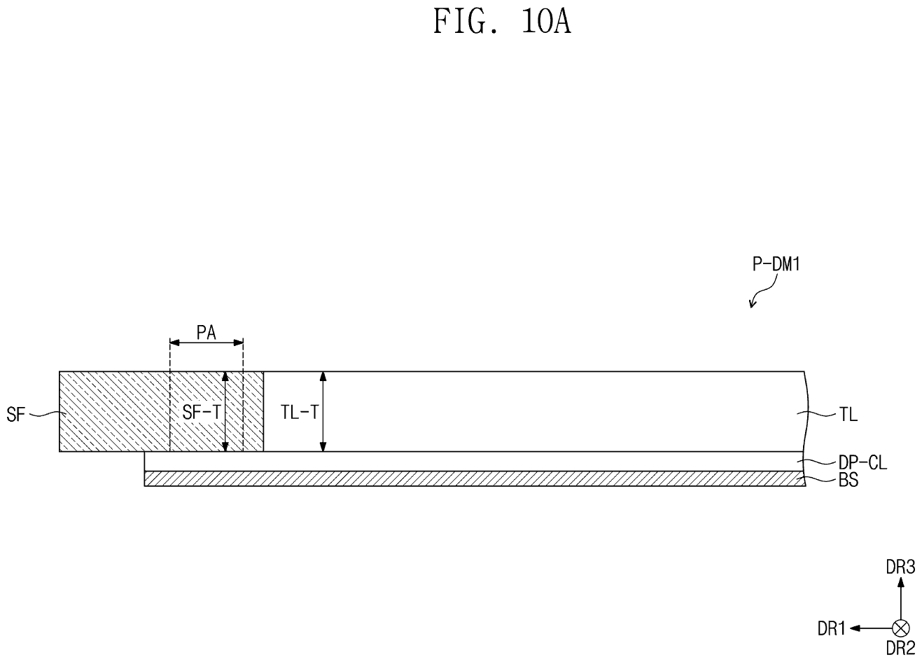

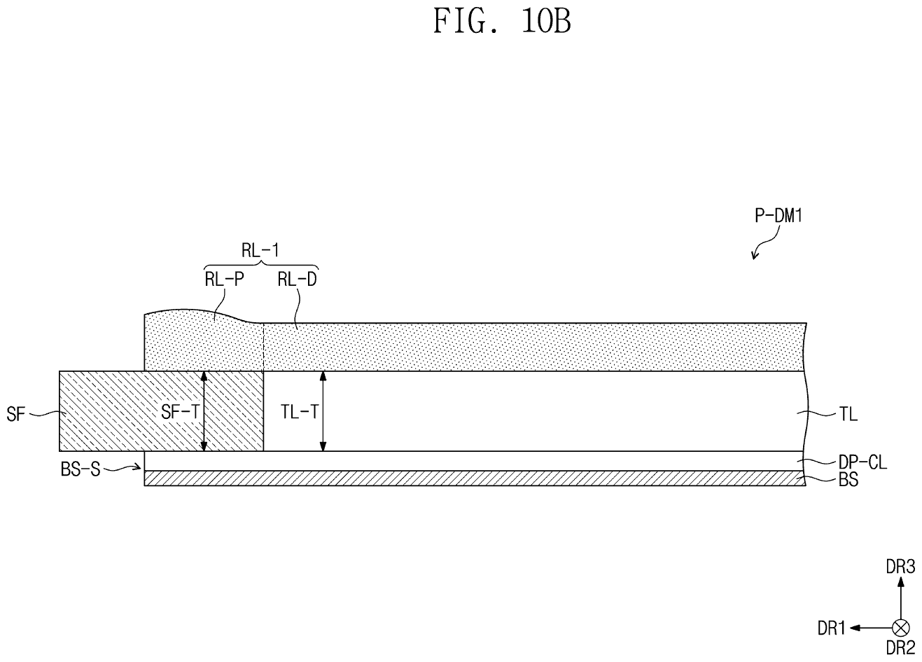

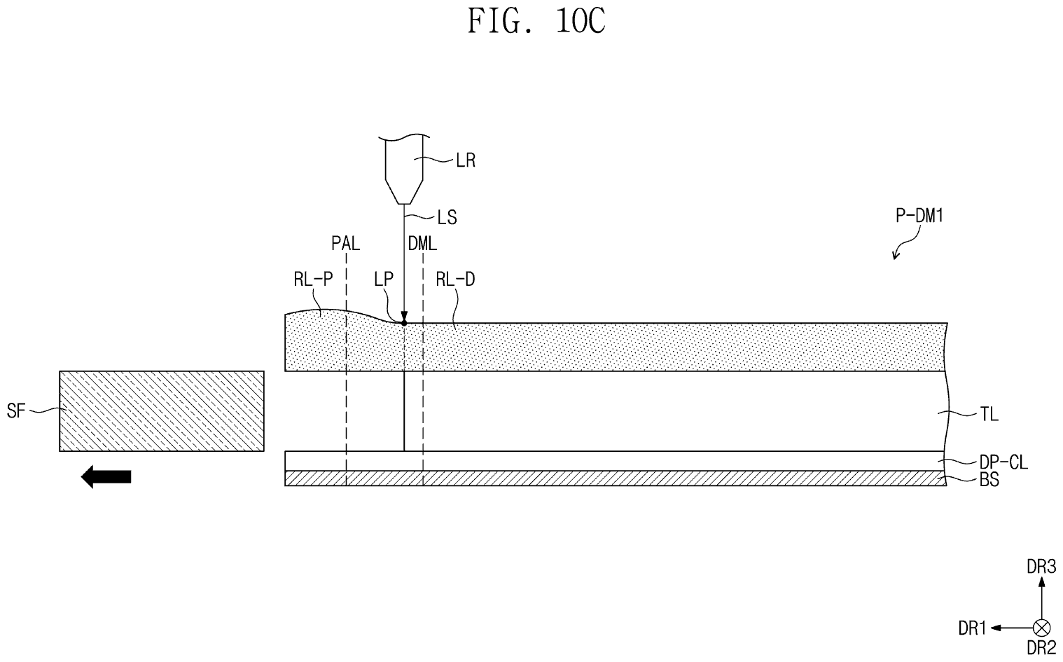

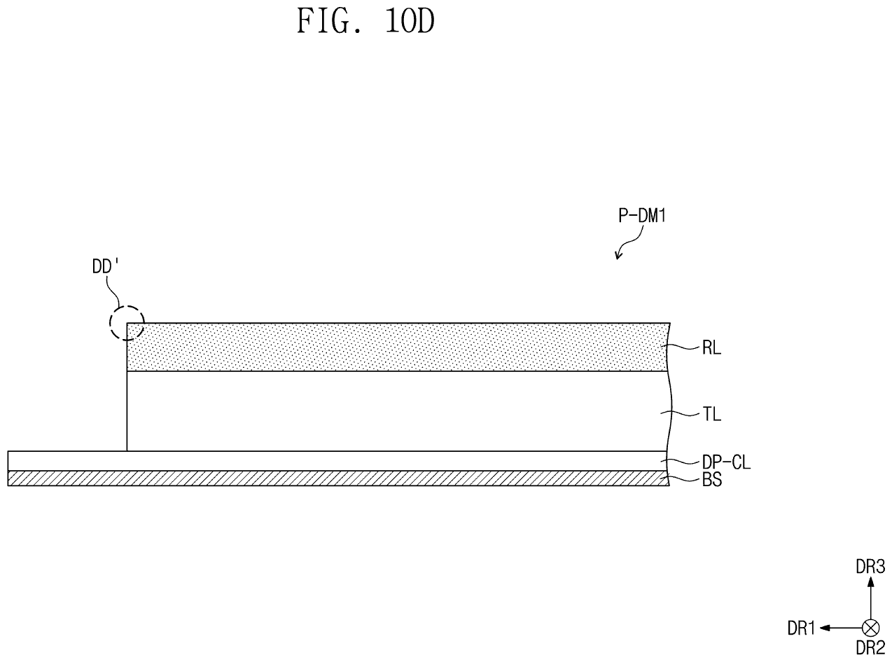

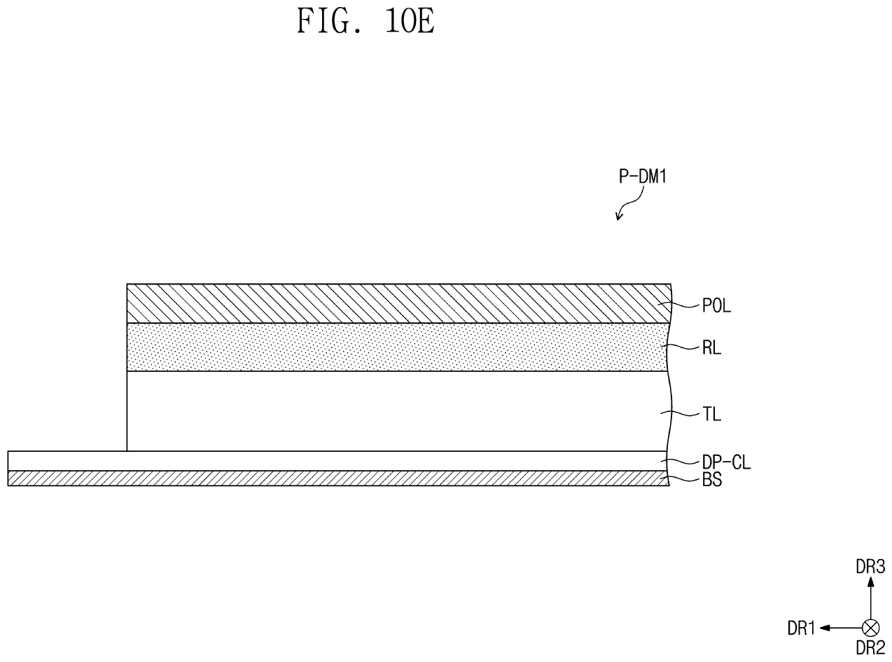

FIGS. 10A to 10E are views of a method of manufacturing the display module DM-1 according to an embodiment of the present disclosure.

Hereinafter, the manufacturing method of the display module DM-1 will be described with reference to FIGS. 10A to 10E. In FIGS. 10A to 10E, processes that are the same as or similar to those of the manufacturing method described with reference to FIGS. 6A to 8D will be omitted, and descriptions will be focused on different features.

Referring to FIG. 10A, the method may include disposing the auxiliary film SF on the base substrate BS in the non-display area NDA.

The auxiliary film SF may be disposed adjacent to a side portion of an encapsulation element layer TL. The auxiliary film SF may be disposed such that the auxiliary film SF overlaps a mounting area PA. The auxiliary film SF may provide a base surface for forming a resin layer RL-1 described later. In the present disclosure, the auxiliary film SF may be a release film. Each side of the auxiliary film SF may be coated with a silicone release agent which may help the auxiliary film SF release easier.

In this case, the auxiliary film SF may have a thickness SF-T equal to or greater than a maximum height TL-T from an upper surface of a circuit element layer DP-CL to an upper surface of the encapsulation element layer TL. That is, in the method of manufacturing the display module according to the present embodiment, both the placement and the removal of the auxiliary film SF are performed, and thus, the method includes providing the auxiliary film SF such that the auxiliary film SF has a certain thickness or more for the precise movement.

A side surface of the auxiliary film SF and a side surface of the encapsulation element layer TL may face each other.

FIG. 10A illustrates a structure in which the side surface of the auxiliary film SF is in contact with the side surface of the encapsulation element layer TL as a representative example, however, the present disclosure should not be limited thereto or thereby. As an example, when the display module DM-1 includes an additional dam pattern, the auxiliary film SF may be spaced apart from the encapsulation element layer TL by a predetermined distance.

However, when the auxiliary film SF is spaced apart from the encapsulation element layer TL by a distance greater than a threshold distance, the base surface on which the resin layer RL-1 (refer to FIG. 10B) is formed may not be provided. Accordingly, embodiments of the present disclosure include disposing the auxiliary film SF such that auxiliary film SF overlaps at least a portion of the mounting area PA.

Referring to FIG. 10B, the method may include forming the resin layer RL-1 on an upper surface of the encapsulation element layer TL and the auxiliary film SF. The resin layer RL-1 may include the resin overlap portion RL-D extending in the direction toward the display area DA (refer to FIG. 4A) with respect to the dam portion DMP (refer to FIG. 4B) and the resin protruding portion RL-P protruding from the resin overlap portion RL-D toward the side surface BS-S of the base substrate BS and overlapping at least the portion of the auxiliary film SF.

Referring to FIG. 10C, the method may include removing the auxiliary film SF and cutting (i.e., cutting out) the resin protruding portion RL-P. Cutting the resin protruding portion may include removing all or a portion of the resin protruding portion. The auxiliary film SF may be removed after moving in the first direction DR1 or the second direction DR2 not to damage the resin layer RL.

The cutting of the resin protruding portion RL-P may include irradiating a cutting point LP between a first boundary DRL and a second boundary PAL with a laser light LS by using a laser emitter LR to cut the resin protruding portion RL-P.

Referring to FIG. 10D, the upper surface and the side surface of the resin layer RL may be perpendicular to each other as illustrated in an area DD′.

Referring to FIG. 10E, the method may include forming an optical layer POL on the flat upper surface provided by the resin layer RL. The forming of the optical layer POL may be performed by a lamination process.

Then, the method may include performing processes that are the same as or similar to those described with reference to FIG. 8D to mount a driving chip D-IC (refer to FIG. 9A) included in a driving module EM (refer to FIG. 9A), to place a printed circuit board PCB (refer to FIG. 9A) on a rear surface of a cover panel CP (refer to FIG. 9A), and to bend and attach a flexible circuit film FCB (refer to FIG. 9A). Accordingly, the display module DM-1 (refer to FIG. 9A) may be formed.

Although the embodiments of the present disclosure have been described, it is understood that the present disclosure should not be limited to the example embodiments but various changes and modifications can be made by one ordinary skilled in the art within the spirit and scope of the present disclosure as hereinafter claimed. Therefore, the disclosed subject matter should not be limited to any single embodiment described herein, and the scope of the embodiments of the present disclosure shall be determined according to the attached claims.

What is claimed is:

1. A method of manufacturing a display module, comprising:
providing a preliminary display module comprising: a base substrate comprising a display area and a non-display area adjacent to the display area, a pixel disposed on the base substrate, a dam portion disposed in the non-display area, and an encapsulation layer disposed on the base substrate and covering the pixel and the dam portion;
forming a film layer on the encapsulation layer, wherein the film layer comprises a first film portion extending in a direction toward the display area with respect to the dam portion and a second film portion extending from the first film portion toward a side surface of the base substrate and surrounding at least a portion of the first film portion;
forming a resin layer on the film layer, wherein the resin layer comprises a first resin portion overlapping the first film portion and a second resin portion overlapping the second film portion; and
cutting the second film portion and the second resin portion.

2. The method of claim 1, wherein the forming of the film layer comprises forming a coating of an adhesive material on the encapsulation layer.

3. The method of claim 2, wherein the forming of the film layer comprises:
disposing a capping film on the coating of the adhesive material; and
laminating the capping film.

4. The method of claim 1, wherein the film layer has an isotropic optical property and comprises an acrylic-based polymer material.

5. The method of claim 1, wherein the forming of the resin layer is performed by one of a dispensing process, an inkjet process, and a slit coating process.

6. The method of claim 1, wherein:
the encapsulation layer comprises a first inorganic layer, an organic layer, and a second inorganic layer, which are sequentially stacked, and
the dam portion is covered by the first inorganic layer and the second inorganic layer.

7. The method of claim 1, wherein:
the preliminary display module comprises a dam pattern, and
the dam portion is disposed relatively closer to an interior of the base substrate compared to the dam pattern.

8. The method of claim 1, wherein a side surface of the resin layer and an upper surface of the resin layer are perpendicular to each other.

9. The method of claim 1, further comprising forming an optical layer, wherein:
the cutting of the second film portion and the second resin portion is performed by a laser cutting process using a laser emitter, and
the optical layer is formed on the resin layer after the cutting of the second film portion and the second resin portion.

10. The method of claim 1, further comprising:
forming a cover panel on a rear surface of the preliminary display module;
forming a driving chip on the preliminary display module in the non-display area; and
forming a circuit board on a rear surface of the cover panel.

11. The method of claim 1, wherein a side surface of the film layer and a side surface of the resin layer are disposed more inward within the display module compared to an outer portion of the base substrate.

12. A method of manufacturing a display module, comprising:
providing a preliminary display module comprising: a base substrate comprising a display area and a non-display area adjacent to the display area, a pixel disposed on the base substrate, a dam portion disposed in the non-display area, and an encapsulation layer covering the pixel;
disposing an auxiliary film on the base substrate such that auxiliary film overlaps the non-display area;
forming a resin layer on the encapsulation layer and the auxiliary film, wherein the resin layer comprises a resin overlap portion extending in a direction toward the display area with respect to the dam portion and a resin protruding portion extending from the resin overlap portion toward a side surface of the base substrate and overlapping at least a portion of the auxiliary film;
removing the auxiliary film; and
cutting at least a portion of the resin overlap portion.

13. The method of claim 12, wherein:
the auxiliary film is a release film, and
an outer surface of the auxiliary film is coated with a silicon release agent.

14. The method of claim 12, wherein the auxiliary film has a thickness equal to or greater than a maximum height from an upper surface of a circuit element layer of the display module to an upper surface of the encapsulation layer.

15. The method of claim 12, wherein:
the cutting of at least the portion of the resin overlap portion comprises a laser cutting process, and
a side surface of the resin layer and an upper surface of the resin layer are perpendicular to each other.

16. A display module comprising:
a base substrate comprising a display area and a non-display area adjacent to the display area;
a circuit element layer disposed on the base substrate;
an encapsulation layer disposed on the circuit element layer;
a film layer which is disposed on the encapsulation layer and optically transparent;
a resin layer disposed on the film layer; and
an optical layer disposed on the resin layer,
wherein a side surface of the film layer and a side surface of the resin layer are aligned with each other in a direction.

17. The display module of claim 16, further comprising an adhesive layer disposed between the encapsulation layer and the film layer,
wherein:
the base substrate comprises a glass material, and
the film layer has an isotropic optical property.

18. The display module of claim 16, further comprising a driving chip, wherein:
a mounting area is defined in the non-display area,
the driving chip is disposed on the circuit element layer in the mounting area, and
the side surface of the resin layer and the side surface of the film layer are not in contact with the driving chip.

19. The display module of claim 16, further comprising:
a cover panel disposed on a rear surface of the base substrate;
a driving chip disposed on the base substrate in the non-display area;
a printed circuit board disposed on a lower surface of the cover panel; and
a flexible circuit film electrically connecting a lower surface of the printed circuit board and the circuit element layer of the display module.

20. An electronic device for providing an image, comprising:
a display module;
wheren the display module comprising
a base substrate comprising a display area and a non-display area adjacent to the display area;
a circuit element layer disposed on the base substrate;
an encapsulation layer disposed on the circuit element layer;
an optically transparent film layer disposed on the encapsulation layer;
a resin layer disposed on the film layer; and
an optical layer disposed on the resin layer, wherein a side surface of the film layer and a side surface of the resin layer are aligned with each other in one direction,
a housing providing base space of the display module; and
a window which disposed on the display panel.
